(19) United States
(12) Patent Application Publication
(10) Pub. No.: US 2008/0257714 A1
(43) Pub. Date: Oct. 23, 2008

(54) METHOD OF MAKING A TMR SENSOR HAVING A TUNNEL BARRIER WITH GRADED OXYGEN CONTENT

(75) Inventors: Tsann Lin, Saratoga, CA (US); Daniele Mauri, San Jose, CA (US); Alexander M. Zeltser, San Jose, CA (US)

Correspondence Address: ZILKA-KOTAB, PC- HIT, P.O. BOX 721120, SAN JOSE, CA, 95172-1120, US

(73) Assignee: HITACHI GLOBAL STORAGE TECHNOLOGIES

(21) Appl. No.: 11/737,705

(22) Filed: Apr. 19, 2007

(51) Int. Cl. C23C 14/00

(52) U.S. Cl. 204/192.1

(57) ABSTRACT

A method for manufacturing a tunnel junction magnetoresistive sensor having improved magnetic performance and reliability. The method includes depositing a Mg—O barrier layer in a sputter deposition tool in a chamber having an oxygen concentration that changes. For example, the sputter deposition could be initiated with a first oxygen concentration in the chamber, and then, during the deposition of the barrier layer the oxygen concentration can be reduced.

### FIELD OF THE INVENTION

The present invention relates to the construction of a tunnel junction magnetoresistive sensor and more particularly to a method for constructing a barrier layer that improves the magnetic performance of the sensor.

### BACKGROUND OF THE INVENTION

The heart of a computer's long term memory is an assembly that is referred to as a magnetic disk drive. The magnetic disk drive includes a rotating magnetic disk, write and read heads that are suspended by a suspension arm adjacent to a surface of the rotating magnetic disk and an actuator that swings the suspension arm to place the read and write heads over selected circular tracks on the rotating disk. The read and write heads are directly located on a slider that has an air bearing surface (ABS). The suspension arm biases the slider toward the surface of the disk and when the disk rotates, air adjacent to the surface of the disk moves along with the disk. The slider flies on this moving air at a very low elevation (fly height) over the surface of the disk. This fly height can be on the order of Angstroms. When the slider rides on the air bearing, the write and read heads are employed for writing magnetic transitions to and reading magnetic transitions from the rotating disk. The read and write heads are connected to processing circuitry that operates according to a computer program to implement the writing and reading functions.

The write head includes a coil layer embedded in first, second and third insulation layers (Insulation stack), the insulation stack being sandwiched between first and second pole piece layers. A gap is formed between the first and second pole piece layers by a gap layer at an air bearing surface (ABS) of the write head and the pole piece layers are connected at a back gap. Current conducted to the coil layer induces a magnetic flux in the pole pieces which causes a magnetic field to fringe out at a write gap at the ABS for the purpose of writing the aforementioned magnetic impressions in tracks on the moving media, such as in circular tracks on the aforementioned rotating disk.

In recent read head designs a spin valve sensor, also referred to as a giant magnetoresistive (GMR) sensor, has been employed for sensing magnetic fields from the rotating magnetic disk. This sensor includes a nonmagnetic conductive layer, referred to as a spacer layer, sandwiched between first and second ferromagnetic layers, hereinafter referred to as a pinned layer and a free layer. First and second leads are connected to the spin valve sensor for conducting a sense current therethrough. The magnetization of the pinned layer is pinned perpendicular to the air bearing surface (ABS) and the magnetic moment of the free layer is biased parallel to the ABS, but is free to rotate in response to external magnetic fields. The magnetization of the pinned layer is typically pinned by exchange coupling with an antiferromagnetic layer.

The thickness of the spacer layer is chosen to be less than the mean free path of conduction electrons through the sensor. With this arrangement, a portion of the conduction electrons is scattered by the interfaces of the spacer layer with each of the pinned and free layers. When the magnetizations of the pinned and free layers are parallel with respect to one another, scattering is minimal and when the magnetizations of the pinned and free layer are antiparallel, scattering is maximized. Changes in scattering alter the resistance of the spin valve sensor in proportion to cos Θ, where Θ is the angle between the magnetizations of the pinned and free layers. In a read mode the resistance of the spin valve sensor changes proportionally to the magnitudes of the magnetic fields from the rotating disk. When a sense current is conducted through the spin valve sensor, resistance changes cause potential changes that are detected and processed as playback signals.

More recently, researches have focused on the development of tunnel junction sensors (TMR sensors) also referred to as tunnel valves. Tunnel valves TMR sensor offer the advantage of providing improved signal amplitude as compared with GMR sensors. TMR sensors operate based on the spin dependent tunneling of electrons through a thin, electrically insulating barrier layer.

TMR sensors have been constructed by forming barrier layers, such as Mg—O barrier layers, in a sputter deposition chamber. The properties of the barrier layer are very important to TMR sensor performance, however, because of certain difficulties with the deposition process, it has not been possible to construct a barrier layer having optimum physical properties such as uniform oxygen content throughout the thickness of the barrier layer.

For example, during deposition of a Mg—O barrier layer, although the oxygen flow through the chamber may be constant during deposition, the partial pressure of oxygen in the chamber (and thus the oxygen content of the deposited barrier) rises during deposition. This is due in part to the gradual decrease in oxygen gettering by the chamber walls as they become coated with an oxide layer during deposition. In addition, oxygen poisoning of the target in the chamber changes the amount of oxygen being deposited in the barrier layer. These problems result in a barrier layer having an oxygen exposure that rises throughout its thickness and results in a TMR sensor having undesirable magnetic properties.

Therefore, there is a need for a method for constructing a TMR sensor having a barrier layer with optimal physical properties. Such a method would preferably provide for the deposition of a barrier layer that has a substantially constant oxygen content of a desired amount.

### SUMMARY OF THE INVENTION

The present invention provides a tunnel junction sensor having improved performance and reliability. A Mg—O barrier layer of the tunnel junction sensor is deposited in a sputter deposition chamber in an atmosphere that contains oxygen and an inert gas such as Ar. The oxygen in the chamber has a concentration that changes during barrier layer deposition.

For example, the concentration of oxygen can start at a relatively high value and can decrease during deposition to a lower oxygen concentration. The reduction in oxygen concentration can stop and actually reverse any target poisoning that occurred during the deposition at higher oxygen concentration. The reduced oxygen concentration can also counteract the effects of reduced oxygen gettering of the chamber walls during deposition.

The deposition process of the present invention advantageously results in a TMR sensor having increased tunneling magnetoresistance (TMR) and increased barrier robustness.

These and other advantages and features of the present invention will be apparent upon reading the following detailed description in conjunction with the Figures.

### BRIEF DESCRIPTION OF THE DRAWINGS

For a fuller understanding of the nature and advantages of this invention, as well as the preferred mode of use, reference should be made to the following detailed description read in conjunction with the accompanying drawings which are not to scale.

FIG. 1 is a schematic illustration of a disk drive system in which the invention might be embodied;

FIG. 2 is an ABS view of a slider, taken from line 3-3 of FIG. 2, illustrating the location of a magnetic head thereon;

FIG. 3 is an ABS view of a tunnel junction sensor according to an embodiment of the present invention taken from circle 3 of FIG. 2;

FIG. 4 is a schematic view of a sputter deposition tool for use in depositing a Mg—O barrier layer in a tunnel junction (TMR) sensor;

FIG. 5 is a flow chart illustrating a method for manufacturing a tunnel junction sensor according to an embodiment of the invention;

FIG. 6 is a flow chart illustrating a method for manufacturing a tunnel junction sensor according to a second embodiment of the invention; and

FIG. 7 is a graph illustrating an improvement in sensor performance provided by the present invention.

### DETAILED DESCRIPTION OF THE PREFERRED EMBODIMENTS

The following description is of the best embodiments presently contemplated for carrying out this invention. This description is made for the purpose of illustrating the general principles of this invention and is not meant to limit the inventive concepts claimed herein.

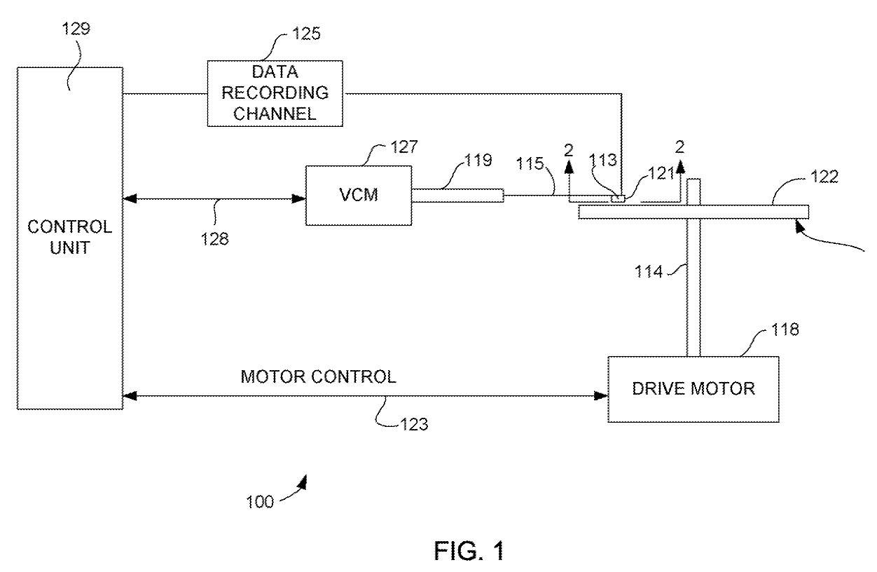

Referring now to FIG. 1, there is shown a disk drive 100 embodying this invention. As shown in FIG. 1, at least one rotatable magnetic disk 112 is supported on a spindle 114 and rotated by a disk drive motor 118. The magnetic recording on each disk is in the form of annular patterns of concentric data tracks (not shown) on the magnetic disk 112.

At least one slider 113 is positioned near the magnetic disk 112, each slider 113 supporting one or more magnetic head assemblies 121. As the magnetic disk rotates, slider 113 moves radially in and out over the disk surface 122 so that the magnetic head assembly 121 may access different tracks of the magnetic disk where desired data are written. Each slider 113 is attached to an actuator arm 119 by way of a suspension 115. The suspension 115 provides a slight spring force which biases slider 113 against the disk surface 122. Each actuator arm 119 is attached to an actuator means 127. The actuator means 127 as shown in FIG. 1 may be a voice coil motor (VCM). The VCM comprises a coil movable within a fixed magnetic field, the direction and speed of the coil movements being controlled by the motor current signals supplied by controller 129.

During operation of the disk storage system, the rotation of the magnetic disk 112 generates an air bearing between the slider 113 and the disk surface 122 which exerts an upward force or lift on the slider. The air bearing thus counter-balances the slight spring force of suspension 115 and supports slider 113 off and slightly above the disk surface by a small, substantially constant spacing during normal operation.

The various components of the disk storage system are controlled in operation by control signals generated by control unit 129, such as access control signals and internal clock signals. Typically, the control unit 129 comprises logic control circuits, storage means and a microprocessor. The control unit 129 generates control signals to control various system operations such as drive motor control signals on line 123 and head position and seek control signals on line 128. The control signals on line 128 provide the desired current profiles to optimally move and position slider 113 to the desired data track on disk 112. Write and read signals are communicated to and from write and read heads 121 by way of recording channel 125.

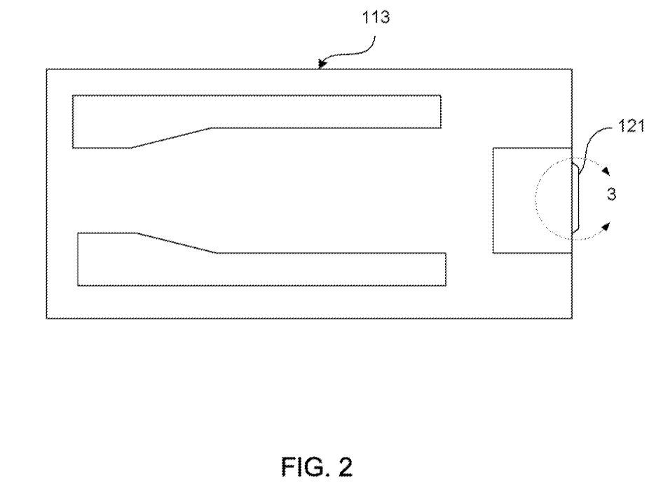

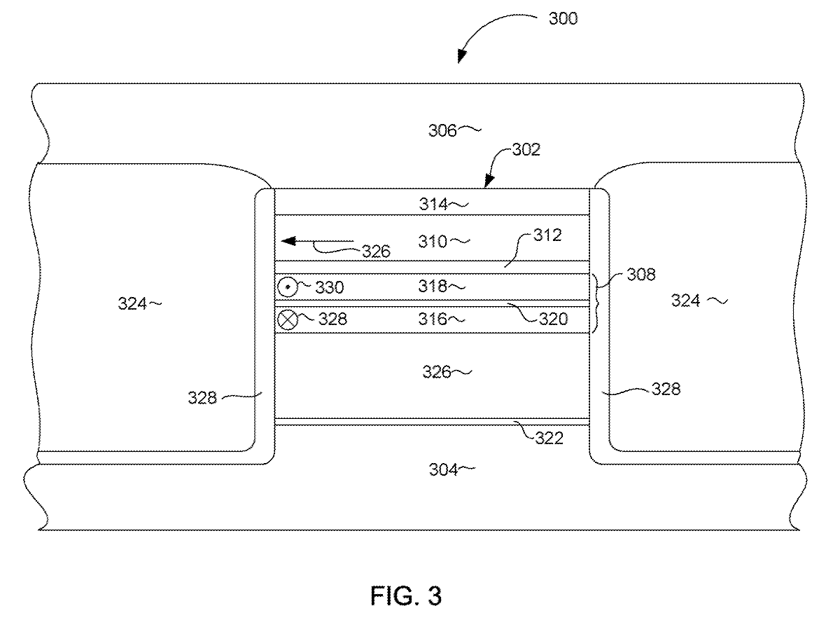

With reference to FIG. 2, the orientation of the magnetic head 121 in a slider 113 can be seen in more detail. FIG. 3 is an ABS view of the slider 113, and as can be seen the magnetic head including an inductive write head and a read sensor, is located at a trailing edge of the slider. The above description of a typical magnetic disk storage system, and the accompanying illustration of FIG. 1 are for representation purposes only. It should be apparent that disk storage systems may contain a large number of disks and actuators, and each actuator may support a number of sliders.

With reference now to FIG. 3, a tunnel junction sensor TMR 300 is described The TMR sensor 300 includes a sensor stack 302 sandwiched between first and second electrically conductive leads 304, 306. The leads 304, 306 can be constructed of an electrically conductive, magnetic material such as NiFe or CoFe so that they can function as magnetic shields as well as leads. The sensor stack 302 includes a magnetic pinned layer structure 308, and a magnetic free layer structure 310. A thin, non-magnetic, electrically insulating barrier layer 312 is sandwiched between the pinned layer structure 308 and the free layer structure 310. The barrier layer 312 is constructed of Mg—O, and could have a thickness of 8 to 10 Angstroms, although other thicknesses and other barrier layer materials could be used too.

The pinned layer can include first and second magnetic layers AP1 316 and AP2 318 that are antiparallel coupled across a non-magnetic antiparallel coupling layer 320. The AP1 and AP2 layers 316, 318 can be constructed of, for example, Co—Fe, Co—Fe—B or other magnetic alloys and the antiparallel coupling layer 320 can be constructed of, for example, Ru. The free layer 310 can be constructed of a material such as Co—Fe, Co—Fe—B or Ni—Fe or may be a combination of these or other materials.

The AP1 layer 316 is in contact with and exchange coupled with a layer of antiferromagnetic material (ATM layer) 326 such as PtMn, IrMn or some other anti ferromagnetic material. This exchange coupling strongly pins the magnetization of the AP1 layer 316 in a first direction as indicated by arrow tail 328. Antiparallel coupling between the AP1 and AP2 layers 316, 318 strongly pins the magnetization of the AP2 layer in a second direction perpendicular to the ABS as indicated by arrowhead 330.

A capping layer 314 such as Ta, Ta/Ru or Ru/Ta/Ru may be provided at the top of the sensor stack 302 to protect the layers thereof from damage during manufacture. In addition, a seed layer 322 may be provided at the bottom of the sensor stack 302 to initiate a desired crystalline growth in the above deposited layers of the sensor stack 302.

First and second hard bias layers 324 may be provided at either side of the sensor stack 302. The hard bias layers 324 can be constructed of a hard magnetic material such as Co—Pt or Co—Pt—Cr. These hard bias layers 324 are magnetostatically coupled with the free layer 310 and provide a magnetic bias field that biases the magnetization of the tree layer 310 in a desired direction parallel with the ABS as indicated by arrow 326. The hard bias layers 324 can be separated form the sensor stack 302 and from at least one of the leads 304 by a layer of electrically insulating material 328 such as alumina in order to prevent current from being shunted across the hard bias layers 324 between the leads 304, 306.

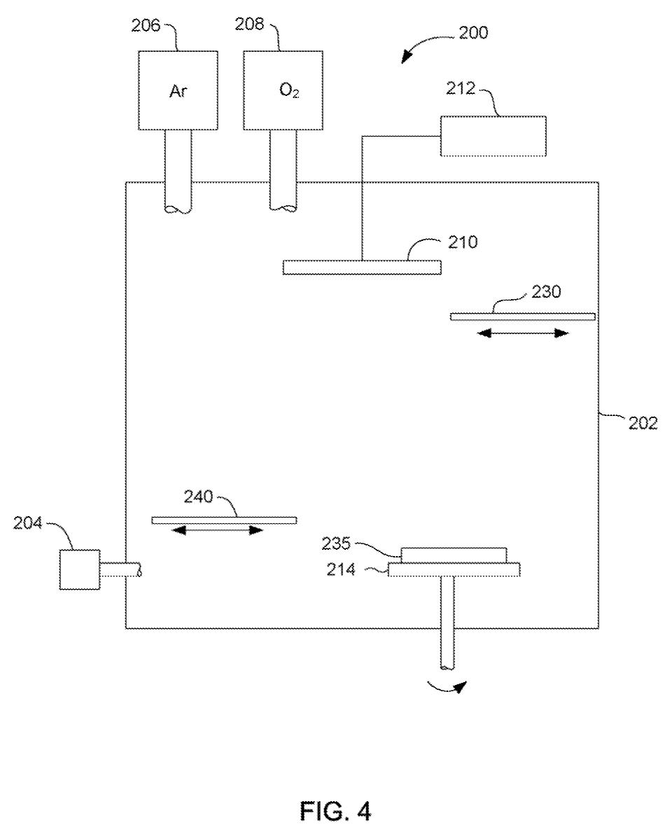

With reference now to FIG. 4, a novel method for depositing the barrier layer 312 (FIG. 3) is described. FIG. 4 is a schematic illustration of a sputter deposition tool 200, which may be an Canon-Anelva® Plasma Vapor Deposition (PVD) tool or a similar sputtering tool. The tool 200 includes a vacuum chamber 202, a cryogenic pump 204, an inert gas supply 206, a reactive gas supply 208, a sputtering target 210, a power supply 212 connected to the target 210, and a rotatable platform 214 for the water. Also included are a shutter 230 to cover the target and a shutter 240 to cover the wafer 235.

The power supply 212 provides power (preferably DC) to the target 210, which results in a plasma being formed in the chamber. Mg atoms from the target 210 are then emitted from the target 210 and sputtered onto the wafer 235. An inert gas, preferably Ar, is entered through a first inlet 206 and a reactive gas 208 is entered through a second inlet 208. As discussed above prior art sputter deposition processes used to deposit Mg—O barrier layers have resulted in inferior quality barrier layers. This has been due to poisoning of the target and also to reduced gettering of the side walls of the vacuum chamber 202. Prior to sputtering, the target is cleaned of any oxides. This is performed by placing the shutter 240 over the wafer 235 (so as to protect the wafer), and placing the shutter 230 over the target 210. Power is then provided to the target 210 without any oxygen in the chamber (only Ar) which sputter cleans the target 210, removing any oxides from the target. Then, the shutter 230 is moved away from the target 210 and sputtering continues without any oxygen in the chamber 202. During this sputtering process, a layer of metal Mg coats the side walls of the chamber 202. Removing any oxides from the target 210 allows effective sputtering to be performed, and coating the side walls of the chamber 202 with Mg increases oxygen gettering during the sputter deposition process.

Then, the shutter 240 is moved away from the wafer 240, and sputtering is performed with both Ar 206 and oxygen 208 being entered into the chamber 202. During prior art sputtering, the oxygen entered into the chamber (which is necessary for constructing a desired Mg—O barrier layer) formed an oxide on the target 210. This is referred to as target poisoning. When the target 210 becomes completely coated with oxide, sputtering almost completely ceases. Since this situation must be avoided, there is a limited range of Oxygen flows that can be used within the prior art method. Furthermore, the addition of oxygen into the chamber 202 forms an oxide on the side walls of the chamber 202. This reduces the oxygen gettering of the side walls, which results in increased oxygen partial pressure in the chamber during deposition. This has been found to result in a barrier layer being formed which has degraded magnetic properties, such as reduced TMR effect.

The present invention prevents poisoning of the target 210 and also can maintain a desired oxygen partial pressure in the chamber 202 during Mg—O deposition. This results in a barrier layer being formed that has vastly improved magnetic properties such as improved TMR values.

According to one embodiment of the invention, after the target has been cleaned and the sides of the chamber 202 have been coated with Mg as described above, sputtering is initiated. The initiation of sputtering can include a first pre-sputtering performed with only Ar in the chamber 202 and with the target shutter 230 and wafer shutter 240 closed. Then a second pre-sputtering can be performed with Ar and O₂ entered into the chamber 202 and with the wafer shutter 240 closed and the target shutter 230 open. Then, the target shutter 230 is opened initiating actual sputter deposition. A desired first concentration of oxygen (O₂) is entered into the chamber 202 through the inlet 208. During deposition, the amount of oxygen is changed (preferably decreased). This can be a gradual, continuous change in oxygen or can be performed as one or more steps of varying oxygen concentration. After deposition has been completed, a natural oxidation process may optionally be employed. This natural oxidation is performed by exposing the deposited barrier layer to oxygen in the chamber without sputtering (i.e. with the power supply 212 turned off).

When the oxygen concentration is sufficiently reduced during deposition as described above, target poisoning not only stops, but can be reversed, thereby cleaning oxides off of the target 210. In addition, the decreased oxygen concentration counteracts the reduced oxygen gettering of the side walls, resulting in greatly improved magnetic properties of the tunnel barrier layer, as will be shown below. In addition, the resulting barrier layer has been found to have greatly improved reliability. Stress testing, in which a tunnel barrier layer is subjected to a series of voltages, has shown, that a barrier layer deposited by the above method (or by the alternate method described below) is much more robust than a barrier layer formed by a prior art method. Although the reasons for the increase in performance are not entirely understood it is believed that the improved performance is due at least in part to the fact that the resulting barrier layer has a more crystalline structure than prior art barrier layers.

Furthermore, the improved performance was an unexpected result, as it was previously believed that the oxygen concentration needed at the beginning of deposition had to be maintained throughout deposition and could not be changed or reduced without seriously degrading barrier layer properties. As can be seen, this was not the case, as barrier layer properties significantly improved when the barrier layer was deposited with a varying oxygen concentration.

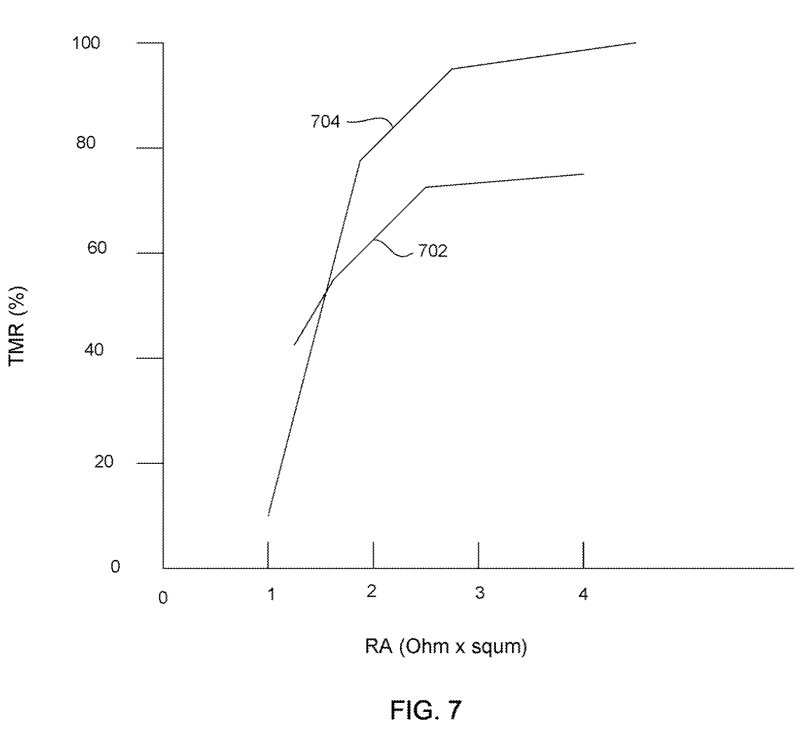

With reference to FIG. 7, the benefits can be seen more clearly. In line 702 shows TMR (Tunneling Magnetoresistance) vs. RA (resistance area product) values for a TMR sensor having a barrier layer deposited with a single oxygen concentration (flow) of 6 sccm. Line 704 shows TMR vs. RA values for a sensor having a barrier layer deposited with a variable oxygen concentration (flow). For the sensor of line 704, the barrier was deposited first at an oxygen flow of 6.8 sccm and then at an oxygen flow of 3 sccm, and as can be seen, the sensor having a barrier deposited with the variable oxygen flow has greatly increased TMR performance values.

In another method for depositing a barrier layer, the barrier layer can be deposited in stages or layers. For example, after cleaning the target and coating the walls of the chamber 202 with Mg, a first sputter deposition stage can be performed with Ar and O₂ being entered into the chamber 202. The deposition is temporarily stopped and an optional target cleaning step can be performed. The cleaning step can include placing the shutter 240 over the wafer 235 and placing the shutter 230 over the target 210. Power is provided to the target 210, which cleans oxides from the target. An optional natural oxidation step may also be performed by allowing the wafer to be exposed to oxygen during the temporary pause in deposition (i.e. while the power is off). Then, after cleaning, (if such cleaning step is performed) the shutters 230, 240 can be moved out of the way, and a second sputter deposition stage performed. Although two deposition stages are discussed above, any number of deposition and cleaning stages could be performed. The oxygen concentration during each of the deposition stages can be varied relative to the other stages. For example, the first deposition stage could be performed at a first oxygen concentration, and then a second deposition could be performed at an oxygen concentration that is less than the first concentration.

The above described deposition can be used to deposit a Mg—O barrier layer such as the barrier layer 312 discussed with reference to FIG. 3. The barrier layer 312 can be deposited after some of the other layers of the sensor stack 302 (FIG. 3) have already been deposited. For example to construct a sensor 300 such as that described with reference to FIG. 3, the AFM layer 326 and pinned layer structure 308 will have already been deposited on the wafer 402 (FIG. 4). However, it should be pointed out that the sensor 300 could have some other configuration. For example, the free layer 310 could be formed beneath the barrier layer 312, in which case the barrier layer 312 would be deposited in the deposition tool 400 (FIG. 4) with the free layer 310 (FIG. 3) already deposited on the wafer 402 (FIG. 4).

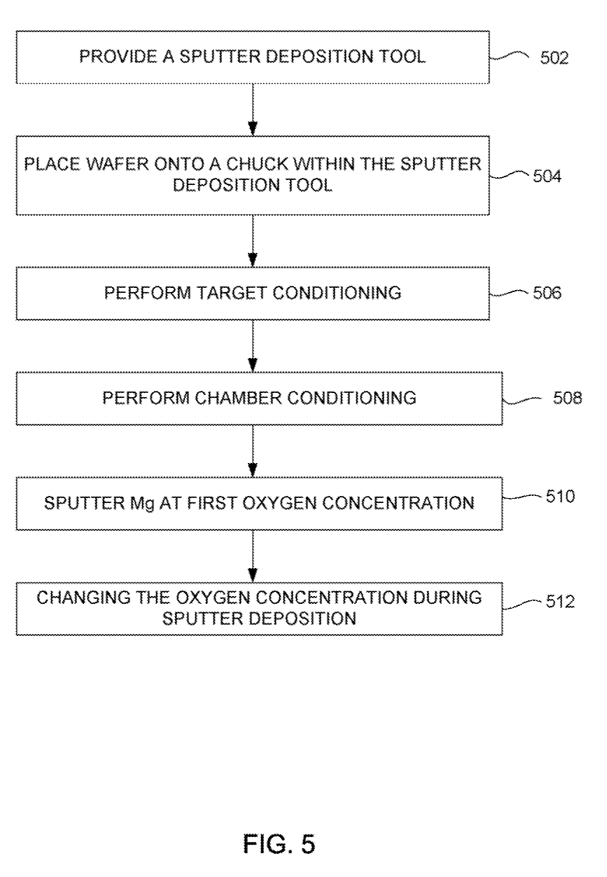

With reference now to FIG. 5 the first method described above can be summarized as follows. In a first step 502, a sputter deposition tool is provided. Then, in a step 504 a wafer is placed onto a chuck within the sputter deposition tool. Then, in a step 506, a target conditioning is performed as described above to remove any oxides from the target. Then, in a step 508 a chamber conditioning is performed as described above to coat the inside of the chamber walls with Mg. Then, in a step 510, sputtering is performed in an oxygen concentration, and in a step 512, during sputter deposition, the oxygen concentration is changed (preferably decreased).

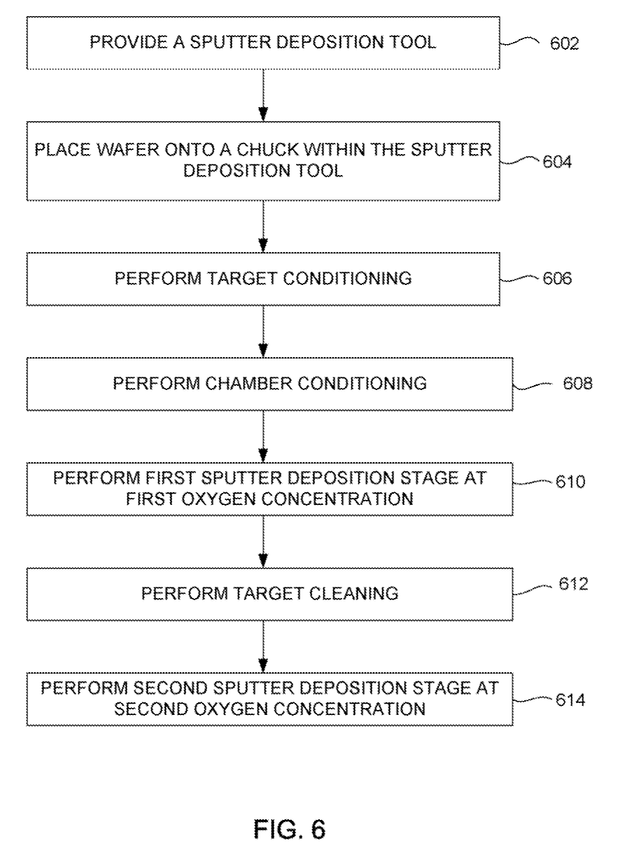

With reference now to FIG. 6 the second method described above can be summarized as follows. First in a step 602 a sputter deposition tool is provided. Then, in a step 604 a wafer is placed onto a chuck within the sputter deposition tool. Then, in a step 606 a target conditioning is performed, and in a step 608 a chamber conditioning is performed. Then, in a step 610 a first sputter deposition stage is performed at a first oxygen concentration. In a step 612 a target cleaning is performed, and then in a step 614 a second sputter deposition stage is performed which may be at an oxygen concentration that is different from (preferably less than) the oxygen concentration of the first or preceding sputter deposition stage 610. Any number of sputter deposition and target cleaning steps 612, 614 can be performed.

While various embodiments have been described above, it should be understood that they have been presented by way of example only, and not limitation. For example, although the barrier layer and method deposition thereof, has been described in terms of a Mg—O barrier layer and the use of a Mg—O target, the invention could also be used to deposit barrier layer constructed of some other oxide. Therefore, the invention is not limited to the deposition of Mg—O barrier layers only, but encompasses the deposition of barrier layer of other materials. Other embodiments falling within the scope of the invention may also become apparent to those skilled in the art. Thus, the breadth and scope of the invention should not be limited by any of the above-described exemplary embodiments, but should be defined only in accordance with the following claims and their equivalents.

What is claimed is:

1. A method for manufacturing a magnetoresistive tunnel junction sensor, the method comprising:
providing a sputter deposition tool;
placing a wafer into the sputter deposition tool;
sputter depositing Mg—O from a Mg target onto the wafer; and
introducing a gas into the sputter deposition tool, the gas having an oxygen concentration, and varying the oxygen concentration.

2. A method as in claim 1 wherein the varying the oxygen concentration includes decreasing the oxygen concentration.

3. A method as in claim 1 wherein the varying the oxygen concentration is performed during the deposition of Mg—O.

4. A method as in claim 1 wherein the varying the oxygen concentration comprises continuously decreasing the oxygen concentration during the deposition of Mg—O.

5. A method as in claim 1 wherein the varying the oxygen concentration comprises a stepwise decrease in oxygen concentration during the deposition of Mg—O.

6. A method as claim 1 wherein the varying the oxygen concentration comprises starting with a first oxygen concentration at the beginning of the Mg—O deposition and ending with a second oxygen concentration at the end of the Mg—O deposition of less than half of the first concentration.

7. A method as in claim 1 wherein the oxygen concentration is varied so as to produce a Mg—O barrier providing a highest possible TMR ratio for a given Mg—O layer thickness and with a highest breakdown voltage.

8. A method as in claim 1 wherein the Mg deposition is performed for a duration to produce a Mg—O barrier layer having a thickness of 6 to 10 Angstroms.

9. A method as in claim 1 further comprising performing a natural oxidation of the deposited Mg.

10. A method for manufacturing a magnetoresistive tunnel junction sensor, comprising:
providing a sputter deposition tool;
placing a wafer into the sputter deposition tool;
performing a first Mg—O sputter deposition stage at a first oxygen concentration;
terminating the first Mg—O deposition and
performing a second Mg—O sputter deposition stage at a second oxygen concentration that is different from the first oxygen concentration.

11. A method for manufacturing a magnetoresistive tunnel junction sensor, comprising:
providing a sputter deposition tool that includes a chamber, a Mg target, a power source connected with the target and a gas inlet;
placing a wafer into the chamber of the sputter deposition tool;
performing a first Mg—O sputter deposition by activating the power source while introducing oxygen at a first concentration into the chamber;
temporarily de-activating the power source; and
performing a second Mg—O sputter deposition while introducing oxygen at a second concentration into the chamber, the second concentration being different than the first concentration.

12. A method as in claim 11 wherein the performing a first sputter deposition, performing a target sputter cleaning process and performing a second sputter deposition together define a cycle, and wherein the method further comprises performing a plurality of cycles.

13. A method as in claim 11 further comprising:
after performing the second sputter deposition, performing a third sputter deposition while introducing oxygen at a third concentration into the chamber, wherein the third concentration is different than the first and second concentrations.

14. A method as in claim 11 wherein the first concentration is greater than the second concentration.

15. A method as in claim 11 further comprising, prior to performing the first sputter deposition, performing a target conditioning step and performing a chamber conditioning step.

16. A method as in claim 11 further comprising performing a natural oxidation.

17. A method as in claim 11 further comprising after each of the first and second sputter deposition steps, performing a natural oxidation.

18. A method as in claim 1 further comprising after performing the sputter deposition, performing a natural oxidation.

19. A method as in claim 10 further comprising after each of the first and second sputter deposition stages, performing a natural oxidation.

20. A method as in claim 13 further comprising, prior to performing the sputter deposition, performing a target conditioning process and performing a chamber conditioning process.

21. A method as in claim 10 further comprising, alter terminating the first Mg—O deposition stage, performing a sputter conditioning process.

22. A method as in claim 11 further comprising, after temporarily de-activating the power source, performing a sputter conditioning process.

23. A method for manufacturing a magnetoresistive tunnel junction sensor, the method comprising:
providing a sputter deposition tool;
placing a wafer into the sputter deposition tool;
sputter depositing metal oxide from a metal target onto the wafer; and
introducing a gas into the sputter deposition tool, the gas having an oxygen concentration, and varying the oxygen concentration.

24. A method for manufacturing a magnetoresistive tunnel junction sensor, comprising:
providing a sputter deposition tool;
placing a wafer into the sputter deposition tool;
performing a first metal oxide sputter deposition stage at a first oxygen concentration;
terminating the first metal oxide deposition and
performing a second metal oxide sputter deposition stage at a second oxygen concentration that is different from the first oxygen concentration.

25. A method for manufacturing a magnetoresistive tunnel junction sensor, comprising:
providing a sputter deposition tool that includes a chamber, a metal target, a power source connected with the target and a gas inlet;
placing a wafer into the chamber of the sputter deposition tool;
performing a first metal sputter deposition by activating the power source while introducing oxygen at a first concentration into the chamber;
temporarily de-activating the power source; and
performing a second metal sputter deposition while introducing oxygen at a second concentration into the chamber, the second concentration being different than the first concentration.
